(19) United States
(12) Patent Application Publication
(10) Pub. No.: US 2024/0377725 A1
(43) Pub. Date: Nov. 14, 2024

(54) PELLICLE

(71) Applicant: MITSUI CHEMICALS, INC., Chuo-ku, Tokyo (JP)

(72) Inventors: Ken ITO, Hiroshima-shi, Hiroshima (JP); Yasushi SATOH, Funabashi-shi, Chiba (JP); Takashi UNEZAKI, Ichihara-shi, Chiba (JP); Yosuke ONO, Sodegaura-shi, Chiba (JP)

(73) Assignee: MITSUI CHEMICALS, INC., Chuo-ku, Tokyo (JP)

(21) Appl. No.: 18/690,350

(22) PCT Filed: Sep. 12, 2022
(86) PCT No.: PCT/JP2022/034109

§ 371 Date: Mar. 8, 2024

(30) Foreign Application Priority Data
Sep. 13, 2021 (JP) 2021-148632

(51) Int. Cl. G03F 1/64

(52) U.S. Cl. CPC G03F 1/64

(57) ABSTRACT

A pellicle includes: a pellicle frame; a pellicle film supported at one end surface of the pellicle frame; and an adhesive layer provided at another end surface of the pellicle frame. The adhesive layer has a swelling degree, which is represented by the following Equation (A), of 200% or lower. Equation (A): [post-immersion mass of 10-mg test piece collected from the adhesive layer/10 mg]×100. In Equation (A), the post-immersion mass represents a mass of the test piece after a 6-hour immersion of the test piece in 10 ml of a decane solution having a capillary column GC concentration of 99.0% or higher.

### TECHNICAL FIELD

The present disclosure relates to a pellicle.

### BACKGROUND ART

The pattern width of semiconductor integrated circuits has been increasingly refined in association with increase in the functions of semiconductor exposure process. In the exposure process, defective exposure may occur when foreign matters such as dust adhere to a photomask, causing a reduction in the yield of a semiconductor integrated circuit. In order to inhibit the adhesion of foreign matters such as dust to the surface of the photomask, a pellicle, which is a photomask cover, is attached to the photomask.

In recent years, with enhancement in the resolution of exposure patterns, the use of extreme ultra violet (EUV) light having a shorter wavelength as an exposure light source has been expanded in place of using deep ultra violet (DUV) light.

In association with such reduction in the wavelength of the exposure light, contamination (hereinafter, also referred to as “haze”) of a pellicle film or a photomask caused by exposure occurs at an increasing frequency. The cause of such haze is believed to be an organic gas component (hereinafter, also referred to as “outgas”) generated from an adhesive and the like during exposure.

Patent Document 1 discloses a pellicle that effectively inhibits the occurrence of haze on a photomask. The pellicle disclosed in Patent Document 1 includes: a pellicle frame; a pellicle film formed on one end surface of the pellicle frame; and an adhesive formed on the other end surface of the pellicle frame. This adhesive is composed of a prescribed adhesive composition. A total mass of a polymerization initiator in the adhesive is 8 ppm or less with respect to a total weight of the adhesive.

Patent Document 2 discloses a pellicle in which an adhesive itself used herein is imparted with an organic gas adsorption capacity, and which is thereby enabled to inhibit the haze-causing adsorption of an organic gas to a photomask. The pellicle disclosed in Patent Document 2 includes: a pellicle frame; a pellicle film formed on one end surface of the pellicle frame; and an adhesive formed on the other end surface of the pellicle frame. This adhesive has a weight swelling degree with toluene of 5 times or more. The “weight swelling rate” refers to a rate of increase in the weight of an elastic gel (adhesive) due to absorption of a liquid (solvent).

### RELATED ART DOCUMENTS

### Patent Documents

[Patent Document 1] Japanese Patent Application Laid-Open (JP-A) No. 2011-107469
[Patent Document 2] JP-A No. 2011-128605

### SUMMARY OF THE INVENTION

### Technical Problem

As required properties of a pellicle, the pellicle is required to inhibit the adhesion of foreign matters to a photomask and to allow an exposure light to efficiently pass through a pellicle film. Particularly, with the progress of miniaturization in recent years, there is a need for a further reduction in an amount of outgas generated by exposure. In addition, there is a need for inhibition of the occurrence of outgas-induced adhesion and the like of a carbon film (hereinafter, referred to as “contamination”) to a pellicle film and the inside of an exposure device even in the use of a pellicle over a longer period.

In other words, there is a demand for a pellicle that is less likely to generate outgas.

The disclosure was made in view of the above-described circumstances.

An object of one embodiment of the disclosure is to provide a pellicle that is less likely to generate outgas.

### Solution to Problem

Means for solving the above-described problem encompass the following embodiments.
<1> A pellicle, including:
a pellicle frame;
a pellicle film supported at one end surface of the pellicle frame; and
an adhesive layer provided at another end surface of the pellicle frame,
wherein the adhesive layer has a swelling degree, which is represented by the following Equation (A), of 200% or lower:

[post-immersion mass of 10-mg test piece collected from the adhesive layer/10 mg]×100 Equation (A):
wherein, in Equation (A), the post-immersion mass represents a mass of the test piece after a 6-hour immersion of the test piece in 10 ml of a decane solution having a capillary column GC concentration of 99.0% or higher.
<2> The pellicle according to <1>, wherein the adhesive layer has a glass transition temperature Tg of from −25° C. to 10° C.
<3> The pellicle according to <1> or <2>, wherein the adhesive layer contains a copolymer of an alkyl (meth)acrylate monomer and a monomer having a functional group that is reactive with at least one of an isocyanate group, an epoxy group, or an acid anhydride.
<4> The pellicle according to <3>, wherein the alkyl (meth)acrylate monomer contains at least one of an alkyl group having from 1 to 3 carbon atoms or an alicyclic alkyl group.
<5> The pellicle according to <3> or <4>, wherein the content of the alkyl (meth)acrylate monomer is from 80 parts by mass to 99.5 parts by mass with respect to a total of 100 parts by mass of the monomers configuring the copolymer.
<6> The pellicle according to any one of <3> to <5>, wherein the content of the monomer having the functional group is from 0.5 parts by mass to 20 parts by mass with respect to a total of 100 parts by mass of the monomers configuring the copolymer.
<7> The pellicle according to any one of <3> to <6>, wherein:
the adhesive layer contains a reaction product of the copolymer and a crosslinking agent, and
the content of the crosslinking agent is from 0.002 parts by mass to 3.000 parts by mass with respect to a total of 100 parts by mass of the monomers configuring the copolymer.
<8> The pellicle according to any one of <1> to <7>, wherein an amount of generated outgas, which is determined by converting an amount of gas generated by performing the following (a) to (d) in the following order into an amount of n-decane, is 1.5 μg or less:
(a) heating the pellicle at 120° C. for 20 hours;
(b) storing the pellicle in a hermetically sealed resin bag for 2 weeks in a 25° C. air atmosphere;
(c) allowing an adsorbent to absorb a gas released by heating the pellicle at 50° C. for 4 hours; and
(d) heating the adsorbent for 10 minutes to measure the amount of the gas adsorbed in (c).

### Advantageous Effects of Invention

According to the disclosure, a pellicle that is less likely to generate outgas is provided.

### BRIEF DESCRIPTION OF DRAWING

FIG. 1 is a schematic cross-sectional view illustrating a cross-section of a pellicle according to Example.

### DESCRIPTION OF EMBODIMENTS

In the disclosure, those numerical ranges that are expressed with “to” each means a range that includes the numerical values stated before and after “to” as the minimum value and the maximum value, respectively.

In a set of numerical ranges that are stated in a stepwise manner in the disclosure, the upper limit value or the lower limit value of one numerical range may be replaced with the upper limit value or the lower limit value of other numerical range, or may be replaced with a relevant value indicated in any of Examples.

In the disclosure, a combination of two or more preferred aspects is a more preferred aspect.

In the disclosure, when there are plural kinds of substances that correspond to a component, an indicated amount of the component means, unless otherwise specified, a total amount of the plural kinds of substances.

In the disclosure, the term “step” encompasses not only a discrete step but also a step that cannot be clearly distinguished from other steps, as long as the intended purpose of the step is achieved.

In the disclosure, the expression “(meth)acryl” means one or both of “acryl” and “methacryl”.

### (1) Embodiments

The pellicle according to one embodiment of the disclosure includes a pellicle frame, a pellicle film, and an adhesive layer. The pellicle film is supported at one end surface of the pellicle frame. The adhesive layer is provided at another end surface of the pellicle frame.

In the pellicle according to one embodiment, the adhesive layer has a swelling degree, which is represented by the following Equation (A) (hereinafter, simply referred to as “swelling degree”), of 200% or lower.

[post-immersion mass of 10-mg test piece collected from the adhesive layer/10 mg]×100 Equation (A):

In Equation (A), the post-immersion mass represents a mass of the test piece after a 6-hour immersion of the test piece in 10 ml of a decane solution having a capillary column gas chromatography (GC) concentration of 99.0% or higher.

The term “swelling degree” used herein refers to a mass change rate (%) of a test piece when the test piece is immersed for 6 hours in 10 ml of a decane solution having a capillary column GC concentration of 99.0% or higher.

In the disclosure, the “decane solution having a capillary column GC concentration of 99.0% or higher” refers to a decane solution having a decane purity of 99.0% or higher as measured by capillary column GC. The “decane purity” refers to a ratio of a peak area of decane with respect to a total peak area of a gas chromatogram obtained by measuring the decane solution by capillary column GC.

The pellicle according to one embodiment has the above-described constitution, and is thus less likely to generate outgas. The reason for this is presumed to be mainly the following.

Pellicles are usually shipped in a state of being hermetically sealed in a resin bag by heat sealing or the like (this state is hereinafter referred to as “packaged state”) so as to prevent foreign matters such as dust from adhering to the pellicles. A material of the resin bag is usually produced by decomposition of naphtha. This causes the resin bag to release a hydrocarbon-based gas derived from its material (this gas is hereinafter referred to as “hydrocarbon gas”). Thus, the adhesive layers of conventional pellicles may readily adsorb such a hydrocarbon gas in a packaged state.

EUV light having a short wavelength is readily absorbed by all kinds of substances. Accordingly, exposure with EUV light is performed in a vacuum atmosphere. In addition, during exposure with EUV light, an adhesive layer of a pellicle is expected to be exposed to a high temperature (e.g., from 50° C. to 60° C.).

Therefore, a hydrocarbon gas adsorbed to a conventional adhesive layer is likely to be released from the adhesive layer especially during exposure with EUV light, and may constitute a portion of outgas.

Meanwhile, in one embodiment, the feature that “the adhesive layer has a swelling degree, which is represented by the following Equation (A), of 200% or lower” indicates that the adhesive layer is less likely to absorb a hydrocarbon gas than a conventional adhesive. In other words, in one embodiment, the adhesive layer hardly absorbs a hydrocarbon gas derived from a material of a resin bag in a packaged state. Therefore, in one embodiment, an amount of outgas generated during exposure with EUV light, which outgas originates from a hydrocarbon gas adsorbed to the adhesive layer, is smaller than that of a conventional pellicle. It is presumed that, as a result, the pellicle according to one embodiment is less likely to generate a hydrocarbon gas than a conventional pellicle.

In addition, the pellicle according to one embodiment is less likely to absorb a hydrocarbon gas than a conventional pellicle even when stored in a packaged state over an extended period. As a result, the pellicle according to one embodiment can be made less likely to generate outgas than a conventional pellicle even when stored in a packaged state over an extended period.

For example, in one embodiment, after the pellicle is produced but before the pellicle is put into a packaged state, the adhesive layer is less likely to adsorb a gas contained in an atmosphere to which the pellicle is exposed (e.g., factory air) than a conventional adhesive layer. Further, in one embodiment, even after the pellicle is attached to a photomask inside a vacuum chamber, the adhesive layer is less likely to adsorb a gas inside the vacuum chamber than a conventional adhesive layer.

Therefore, in one embodiment, the amount of outgas generated during exposure with EUV light, which outgas originates from a gas adsorbed to the adhesive layer, is smaller than that of a conventional pellicle. As a result, the pellicle according to one embodiment can be made less likely to generate outgas than a conventional pellicle.

In one embodiment, haze in the pellicle film, which is caused by excitation of a gas due to exposure with EUV light or ArF light, can be made less likely to occur.

### (1.1) Swelling Degree

In one embodiment, the pellicle has a swelling degree of 200% or lower.

An upper limit of the swelling degree is 200% or lower and, from the standpoint of, for example, further reducing the amount of generated outgas originating from decane gas adsorbed to the adhesive layer, the upper limit of the swelling degree is preferably 180% or lower, more preferably 150% or lower, still more preferably 135% or lower.

A lower limit of the swelling degree is not particularly limited, and it is preferably 10% or higher, more preferably 50% or higher, still more preferably 110% or higher.

From these standpoints, the swelling degree is preferably from 10% to 200%, more preferably from 10% to 180%, still more preferably from 10% to 150%, particularly preferably from 10% to 135%, further preferably from 50% to 135%, still further preferably from 110% to 135%.

A method of measuring the swelling degree includes the following steps (A1) to (A7) that are performed in the order mentioned:
(A1) heating the whole pellicle at 120° C. for 20 hours;
(A2) removing the pellicle from a chamber of a heating apparatus, and leaving the pellicle to stand in 25° C. air atmosphere to cool the pellicle to room temperature;
(A3) cutting a portion of the adhesive layer contained in the pellicle to obtain a 10-mg test piece;
(A4) preparing a decane solution having a capillary column GC concentration of 99% or higher;
(A5) immersing the test piece in 10 ml of the decane solution at normal temperature for 6 hours;
(A6) removing the test piece from the decane solution, placing the test piece on a petri dish, and drying the test piece for 3 minutes; and
(A7) measuring the mass of the test piece, and calculating the swelling degree by substituting the thus measured value into Equation (A).

The details of the method of measuring the swelling degree will be described below in the section of Examples.

As a method of adjusting the swelling degree to be 200% or lower, for example, a method of adjusting the adhesive layer to have a glass transition temperature Tg of −25° C. or higher may be employed.

The glass transition temperature Tg of the adhesive layer will be described below.

### (1.2) Amount of Outgas

In one embodiment, the pellicle preferably has an amount of generated outgas, which is determined by converting an amount of gas generated by performing the following (a) to (d) in the following order into an amount of n-decane, of 1.5 μg or less:
(a) heating the pellicle at 120° C. for 20 hours;
(b) storing the pellicle in a hermetically sealed resin bag for 2 weeks in a 25° C. air atmosphere;
(c) allowing an adsorbent to absorb a gas released by heating the pellicle at 50° C. for 4 hours; and
(d) heating the adsorbent for 10 minutes to measure the amount of the gas adsorbed in (c).

The details of a method of measuring the amount of generated outgas will be described below in the section of Examples.

The feature that the amount of generated outgas is 1.50 μg or less indicates that the generation of outgas is less likely to occur. When the amount of generated outgas of the pellicle is in this range, the pellicle can further inhibit the occurrence of haze at the time of exposure.

An upper limit of the amount of generated outgas is more preferably 1.10 μg or less, still more preferably 0.50 μg or less, yet still more preferably 0.30 μg or less, further preferably 0.20 μg or less, still further preferably 0.10 μg or less. The amount of generated outgas is preferably as close to 0 μg as possible.

### (1.3) Adhesive Layer

In one embodiment, the pellicle includes an adhesive layer.

The adhesive layer enables to adhere the pellicle according to one embodiment of a photomask.

The adhesive layer is a gel-like viscoelastic body. The adhesive layer exhibits a viscosity and a cohesive strength. The term “viscosity” used herein refers to such a property of a liquid that gradually wets a photomask, which is an adherend, upon coming into contact therewith. The term “cohesive strength” used herein refers to such a property of a solid that exhibits a resistance to peeling from a photomask.

As described below, the adhesive layer is formed by processing a coating composition through application, heating, drying, curing, and the like.

### (1.3.1) Glass Transition Temperature

The adhesive layer preferably has a glass transition temperature Tg of from −25° C. to 10° C. By this, the pellicle according to one embodiment can be made less likely to generate outgas derived from decane gas adsorbed to the adhesive layer. Further, the adhesive layer exhibits an adhesive strength in a use temperature range (e.g., 20° C. or higher) of the pellicle, making the pellicle less likely to be peeled off from a photomask even when exposed to a high-temperature environment.

A lower limit of the glass transition temperature Tg of the adhesive layer is preferably −25° C. or higher and, from the standpoint of making the generation of outgas less likely to occur, it is more preferably −20° C. or higher, still more preferably −15° C. or higher, most preferably −10° C. or higher.

From the standpoint of imparting an appropriate adhesiveness at normal temperature, an upper limit of the glass transition temperature Tg of the adhesive layer is preferably 10° C. or lower, more preferably 5° C. or lower, still more preferably 0° C. or lower.

From the standpoint of facilitating the reduction of strain of an original plate caused by distortion of the pellicle frame, the upper limit of the glass transition temperature Tg of the adhesive layer is preferably −5° C. or lower, more preferably −10° C. or lower.

From these standpoints, the glass transition temperature Tg is preferably from −25° C. to 5° C., more preferably from −25° C. to 0° C., still more preferably from −25° C. to −5° C., yet still more preferably from −25° C. to −10° C., particularly preferably from −20° C. to −10° C., further preferably from −18° C. to −10° C.

The glass transition temperature Tg of the adhesive layer is measured by the same method as described below in the section of Examples.

### (1.3.2) Coating Composition

The coating composition contains a compound selected from various polymers, solvents, crosslinking agents, catalysts, initiators, and the like in accordance with the adhesive layer to be formed. The coating composition is a precursor of an adhesive composition. In other words, an adhesive composition is obtained by curing the coating composition.

### (1.3.3) Adhesive Composition

Examples of the adhesive composition include, but not particularly limited to, acrylic, silicone-based, styrene butadiene-based, urethane-based, and olefin-based adhesives. Thereamong, from the standpoint of, for example, reducing the amount of outgas generated from the pellicle, the adhesive composition preferably contains an acrylic adhesive.

The acrylic adhesive will now be described.

### (1.3.4) Acrylic Adhesive

The acrylic adhesive preferably contains an alkyl (meth)acrylate copolymer.

### (1.3.4.1) Alkyl (Meth)Acrylate Copolymer

The alkyl (meth)acrylate copolymer preferably contains a copolymer of:

an alkyl (meth)acrylate monomer; and

a monomer having a functional group that is reactive with at least one of an isocyanate group, an epoxy group, or an acid anhydride (this monomer is hereinafter also referred to as “functional group-containing monomer”).

The copolymer of an alkyl (meth)acrylate monomer and a functional group-containing monomer is hereinafter also referred to as “the copolymer”.

The acrylic adhesive contains the alkyl (meth)acrylate copolymer; therefore, the pellicle is unlikely to be peeled off from a photomask even when exposed to a high-temperature environment (e.g., from 50° C. to 60° C.), and the generation of adhesive residue can be inhibited.

The term “adhesive residue” used herein refers to that at least a portion of the adhesive layer remains on a photomask after peeling the pellicle from the photomask.

The alkyl (meth)acrylate copolymer has a weight-average molecular weight (Mw) of preferably from 30,000 to 2,500,000, more preferably from 50,000 to 1,500,000, still more preferably from 70,000 to 1,200,000.

When the weight-average molecular weight (Mw) of the alkyl (meth)acrylate copolymer is in this range, the pellicle is less likely to be peeled off from a photomask even when exposed to a high-temperature environment (e.g., from 50° C. to 60° C.), and the generation of adhesive residue can be further inhibited.

When an upper limit of the weight-average molecular weight (Mw) of the alkyl (meth)acrylate copolymer is 2,500,000 or less, the solution viscosity can be controlled in range where the coating composition can be easily processed even with an increase in the solid concentration of the coating composition. The upper limit of the weight-average molecular weight (Mw) of the alkyl (meth)acrylate copolymer is preferably 2,500,000 or less, more preferably 1,500,000 or less, still more preferably 1,200,000 or less, further preferably 135,000 or less, still further preferably 126,000 or less, yet still further preferably 112,000 or less.

When a lower limit of the weight-average molecular weight (Mw) of the alkyl (meth)acrylate copolymer is 30,000 or more, the pellicle is less likely to be peeled off from a photomask even when exposed to a high-temperature environment (e.g., from 50° C. to 60° C.), and the generation of adhesive residue can be inhibited. The lower limit of the weight-average molecular weight (Mw) of the alkyl (meth)acrylate copolymer is preferably 30,000 or more, more preferably 50,000 or more, still more preferably 70,000 or more.

The weight-average molecular weight (Mw) of the alkyl (meth)acrylate copolymer is measured by gel permeation chromatography (GPC), and the details of a measurement method will be described below in the section of Examples.

For example, generally, a higher monomer concentration during a polymerization reaction tends to lead to a larger weight-average molecular weight (Mw), and a smaller amount of a polymerization initiator and a lower polymerization temperature tend to lead to a larger weight-average molecular weight (Mw). The weight-average molecular weight can be controlled by adjusting the monomer concentration, the amount of the polymerization initiator, and the polymerization temperature.

The alkyl (meth)acrylate copolymer has a number-average molecular weight (Mn) of preferably from 5,000 to 500,000, more preferably from 8,000 to 300,000, still more preferably from 10,000 to 200,000, particularly preferably from 20,000 to 200,000, further preferably from 30,800 to 36,000.

When an upper limit of the number-average molecular weight (Mn) of the alkyl (meth)acrylate copolymer is 500,000 or less, the solution viscosity can be controlled in range where the coating composition can be easily processed even with an increase in the solid concentration of the coating composition. The upper limit of the number-average molecular weight (Mn) of the alkyl (meth)acrylate copolymer is preferably 500,000 or less, more preferably 300,000 or less, still more preferably 200,000 or less.

When a lower limit of the number-average molecular weight (Mn) of the alkyl (meth)acrylate copolymer is 5,000 or more, the pellicle is less likely to be peeled off from a photomask even when exposed to a high-temperature environment (e.g., from 50° C. to 60° C.), and the generation of adhesive residue can be inhibited. The lower limit of the number-average molecular weight (Mn) of the alkyl (meth)acrylate copolymer is preferably 5,000 or more, more preferably 8,000 or more, still more preferably 10,000 or more, most preferably 20,000 or more.

The number-average molecular weight (Mn) of the alkyl (meth)acrylate copolymer is measured by GPC (gel permeation chromatography), and the details of a measurement method will be described below in the section of Examples.

The alkyl (meth)acrylate copolymer has a ratio “weight-average molecular weight (Mw)/number-average molecular weight (Mn)” (hereinafter, also denoted as “Mw/Mn”) of preferably from 1.0 to 10.0, more preferably from 2.0 to 9.0, still more preferably from 2.5 to 8.0, particularly preferably from 3.0 to 7.0, further preferably from 3.3 to 3.7.

When an upper limit of the ratio Mw/Mn is 10.0 or lower, the generation of adhesive residue can be inhibited. The upper limit of the ratio Mw/Mn is preferably 10.0 or lower, more preferably 9.0 or lower, still more preferably 8.0 or lower, most preferably 7.0 or lower.

When a lower limit of the ratio Mw/Mn is 1.0 or higher, the alkyl (meth)acrylate copolymer can be easily produced. The lower limit of the ratio Mw/Mn is preferably 1.0 or higher, more preferably 2.0 or higher, still more preferably 2.5 or higher, most preferably 3.0 or higher.

The alkyl (meth)acrylate monomer preferably contains an alkyl (meth)acrylate monomer containing an alkyl group having from 1 to 14 carbon atoms. The alkyl (meth)acrylate monomer containing an alkyl group having from 1 to 14 carbon atoms is, for example, a (meth)acrylate monomer of a linear aliphatic alcohol, a (meth)acrylate monomer of a branched aliphatic alcohol, or a (meth)acrylate monomer of a cyclic aliphatic alcohol.

Examples of the (meth)acrylate monomer of a linear aliphatic alcohol include methyl (meth)acrylate, ethyl (meth)acrylate, butyl (meth)acrylate, propyl (meth)acrylate, hexyl (meth)acrylate, octyl (meth)acrylate, decyl (meth)acrylate, dodecyl (meth)acrylate, and lauryl (meth)acrylate.

Examples of the (meth)acrylate monomer of a branched aliphatic alcohol include isobutyl (meth)acrylate, isoamyl (meth)acrylate, 2-ethylhexyl (meth)acrylate, isooctyl (meth)acrylate, and isononyl (meth)acrylate.

Examples of the (meth)acrylate monomer of a cyclic aliphatic alcohol include cyclohexyl (meth)acrylate and dicyclopentenyloxyethyl (meth)acrylate.

These monomers may be used singly, or in combination of two or more kinds thereof.

Thereamong, the alkyl (meth)acrylate monomer is preferably one which contains at least one of an alkyl group having from 1 to 3 carbon atoms or an alicyclic alkyl group.

An alkyl (meth)acrylate monomer which contains at least one of an alkyl group having from 1 to 3 carbon atoms or an alicyclic alkyl group is hereinafter referred to as “high-Tg monomer”. It is noted here that “Tg” denotes glass transition temperature.

In order to further reduce the amount of generated outgas, the alkyl (meth)acrylate monomer is more preferably an alkyl acrylate monomer that contains an alkyl group having from 1 to 3 carbon atoms or an alicyclic alkyl group, still more preferably an alkyl acrylate monomer that contains an alkyl group having from 1 to 3 carbon atoms. When the alkyl (meth)acrylate monomer is an alkyl acrylate monomer containing an alicyclic alkyl group, from the standpoint of availability, the number of carbons of the alicyclic alkyl group is preferably from 5 to 10.

By incorporating a high-Tg monomer into the alkyl (meth)acrylate monomer, the pellicle is made unlikely to be peeled off from a photomask even when exposed to a high-temperature atmosphere.

Specific examples of the high-Tg monomer include methyl acrylate, ethyl acrylate, propyl acrylate, isopropyl acrylate, cyclohexyl acrylate, dicyclopentanyl acrylate, methyl methacrylate, ethyl methacrylate, propyl methacrylate, isopropyl methacrylate, cyclohexyl methacrylate, and dicyclopentanyl methacrylate.

Thereamong, in order to further reduce the amount of generated outgas, the alkyl (meth)acrylate monomer preferably contains at least one of an alkyl group having from 1 to 2 carbon atoms or an alicyclic alkyl group, more preferably contains an alkyl group having from 1 to 2 carbon atoms.

The content of the alkyl (meth)acrylate monomer is preferably from 80 parts by mass to 99.5 parts by mass, more preferably from 85 parts by mass to 99.5 parts by mass, still more preferably from 87 parts by mass to 99.5 parts by mass, with respect to a total of 100 parts by mass of the monomers configuring the copolymer.

When the content of the alkyl (meth)acrylate monomer is in a range of from 80 parts by mass to 99.5 parts by mass, an appropriate adhesive strength can be realized.

From the standpoint of further reducing the amount of generated outgas, the content of the alkyl (meth)acrylate monomer, which is at least one of an alkyl group having from 1 to 3 carbon atoms or an alicyclic alkyl group, is preferably in a range of from 80 parts by mass to 99.5 parts by mass. From the same standpoint, the content of the alkyl (meth)acrylate monomer, which is at least one of an alkyl group having from 1 to 2 carbon atoms or an alicyclic alkyl group, is more preferably in a range of from 80 parts by mass to 99.5 parts by mass. From the same standpoint, the content of the alkyl (meth)acrylate monomer which is an alkyl group having from 1 to 2 carbon atoms is more preferably in a range of from 80 parts by mass to 99.5 parts by mass.

The functional group-containing monomer is a monomer copolymerizable with the alkyl (meth)acrylate monomer. The functional group-containing monomer contains a functional group that is reactive with at least one of an isocyanate group, an epoxy group, or an acid anhydride.

The functional group-containing monomer is, for example, a carboxy group-containing monomer, a hydroxy group-containing monomer, or an epoxy group-containing monomer.

Examples of the carboxy group-containing monomer include (meth)acrylic acid, itaconic acid, (meth)acrylic acid-itaconic acid, maleic acid, and crotonic acid.

Examples of the hydroxy group-containing monomer include 2-hydroxyethyl (meth)acrylate, 3-hydroxypropyl (meth)acrylate, 2-hydroxypropyl (meth)acrylate, and 4-hydroxybutyl (meth)acrylate.

Examples of the epoxy group-containing monomer include glycidyl (meth)acrylate.

These monomers may be used singly, or in combination of two or more kinds thereof.

Particularly, from the standpoint of copolymerizability, general versatility, and the like, the functional group-containing monomer preferably contains a hydroxy group-containing (meth)acrylic acid containing a hydroxyalkyl group having from 2 to 4 carbon atoms, or glycidyl (meth)acrylate that is an epoxy group-containing monomer. Examples of the hydroxy group-containing (meth)acrylic acid containing a hydroxyalkyl group having from 2 to 4 carbon atoms include 2-hydroxyethyl (meth)acrylate, 2-hydroxypropyl (meth)acrylate, 2-hydroxybutyl (meth)acrylate, and 4-hydroxybutyl (meth)acrylate.

The content of the functional group-containing monomer is preferably, for example, from 0.5 parts by mass to 20 parts by mass with respect to a total of 100 parts by mass of the monomers configuring the copolymer.

From the standpoint of improving the adhesive strength of the adhesive layer, a lower limit of the content of the functional group-containing monomer is more preferably 1 part by mass or more, still more preferably 2 parts by mass or more, particularly preferably 3 parts by mass or more, with respect to a total of 100 parts by mass of the monomers configuring the alkyl (meth)acrylate copolymer.

From the standpoint of allowing the adhesive layer to have an appropriate adhesive strength, an upper limit of the content of the functional group-containing monomer is more preferably 15 parts by mass or less, still more preferably 10 parts by mass or less, with respect to a total of 100 parts by mass of the monomers configuring the alkyl (meth)acrylate copolymer.

### (1.3.4.2) Polymerization Method

A method of polymerizing the alkyl (meth)acrylate copolymer is not particularly limited, and examples thereof include solution polymerization, bulk polymerization, emulsion polymerization, and various radical polymerization methods.

The alkyl (meth)acrylate copolymer obtained by any of these polymerization methods may be any of a random copolymer, a block copolymer, a graft copolymer, and the like.

### (1.3.4.3) Polymerization Solvent

A reaction solution contains a polymerization solvent.

In solution polymerization, for example, propyl acetate, ethyl acetate, or toluene can be used as the polymerization solvent. By this, the viscosity of the resulting copolymer solution can be adjusted. This consequently makes it easy to control the thickness and the width of the coating composition at the time of the polymerization.

Examples of a dilution solvent include propyl acetate, acetone, ethyl acetate, and toluene.

The viscosity of the copolymer solution is preferably 1,000 Pa·s or less, more preferably 500 Pa·s or less, still more preferably 200 Pa·s or less.

The viscosity of the coating composition is the viscosity determined when the temperature of the coating composition is 25° C., and can be measured using a B-type viscometer.

### (1.3.4.4) Solution Polymerization

One example of solution polymerization is a method of adding a polymerization initiator to a mixed solution of monomers in a stream of inert gas such as nitrogen to perform a polymerization reaction at temperature of from 50° C. to 100° C. for a period of from 4 hours to 30 hours.

The polymerization initiator is, for example, an azo-based polymerization initiator or a peroxide-based polymerization initiator. Examples of the azo-based polymerization initiator include 2,2′-azobisisobutyronitrile (AIBN), 2,2′-azobis-2-methylbutyronitrile, dimethyl-2,2′-azobis(2-methylpropionate), and 4,4′-azobis-4-cyanovaleric acid. Examples of the peroxide-based polymerization initiator include benzoyl peroxide.

The content of the polymerization initiator is preferably from 0.01 parts by mass to 2.0 parts by mass with respect to a total of 100 parts by mass of all monomers configuring the alkyl (meth)acrylate copolymer.

In solution polymerization, in addition to the polymerization initiator, a chain transfer agent, an emulsifying agent, and the like may be added to the mixed solution of monomers. As the chain transfer agent, the emulsifying agent, and the like, any known agents can be selected and used as appropriate.

The amount of the polymerization initiator remaining in the adhesive layer is preferably small. By this, the amount of outgas generated during exposure can be reduced.

Examples of a method of reducing the amount of the polymerization initiator remaining in the adhesive layer include: a method of minimizing the amount of the polymerization initiator added at the time of polymerizing the alkyl (meth)acrylate copolymer; a method of using a polymerization initiator that is readily thermally decomposed; and a method including the steps of applying and drying an adhesive, in which the adhesive is heated to a high temperature for an extended period and the polymerization initiator is decomposed in the drying step.

A 10-hour half-life temperature is used as an index that represents the thermal decomposition rate of the polymerization initiator. A “half-life” represents the time required for one half of the polymerization initiator to be decomposed. A “10-hour half-life temperature” represents the temperature at which the half-life is 10 hours.

As the polymerization initiator, it is preferred to use a polymerization initiator having a low 10-hour half-life temperature. The lower the 10-hour half-life temperature, the more easily is the polymerization initiator thermally decomposed. As a result, the polymerization initiator is less likely to remain in the adhesive layer.

The 10-hour half-life temperature of the polymerization initiator is preferably 80° C. or lower, more preferably 75° C. or lower.

Examples of an azo-based polymerization initiator having a low 10-hour half-life temperature include 2,2′-azobis(4-methoxy-2,4-dimethylvaleronitrile) (10-hour half-life temperature: 30° C.), 2,2′-azobisisobutyronitrile (10-hour half-life temperature: 65° C.), 2,2-azobis(2,4-dimethylvaleronitrile) (10-hour half-life temperature: 51° C.), dimethyl-2,2′-azobis(2-methylpropionate) (10-hour half-life temperature: 66° C.), and 2,2′-azobis(2-methylbutyronitrile) (10-hour half-life temperature: 67° C.).

Examples of a peroxide-based polymerization initiator having a low 10-hour half-life temperature include dibenzoyl peroxide (10-hour half-life temperature: 74° C.) and dilauroyl peroxide (10-hour half-life temperature: 62° C.).

### (1.3.4.5) Crosslinking Agent

A crosslinking agent is a compound that contributes to the formation of a three-dimensional network structure through a reaction of a functional group of the compound with the copolymer. The acrylic adhesive preferably contains a reaction product of the alkyl (meth)acrylate copolymer and such a crosslinking agent. By this, the cohesive strength of the resulting adhesive layer is improved, so that the generation of adhesive residue can be inhibited, and the adhesive strength at a high temperature can be enhanced.

The crosslinking agent has at least one of an isocyanate group, an epoxy group, an acid anhydride, or a radical generating group.

Examples of the crosslinking agent include monofunctional epoxy compounds, polyfunctional epoxy compounds, acid anhydride compounds, metal salts, metal alkoxides, aldehyde compounds, non-amino resin-based amino compounds, urea compounds, isocyanate compounds, metal chelate compounds, melamine compounds, aziridine compounds, azo-based initiators, and organic peroxides.

Thereamong, in terms of having excellent reactivity with a functional group component of the alkyl (meth)acrylate copolymer, the crosslinking agent is more preferably at least one of a monofunctional epoxy compound, a polyfunctional epoxy compound, an isocyanate compound, or an acid anhydride compound, still more preferably an acid anhydride compound.

Examples of the monofunctional epoxy compound include glycidyl (meth)acrylate, glycidyl acetate, butyl glycidyl ether, and phenyl glycidyl ether.

Examples of the polyfunctional epoxy compound include neopentyl glycol diglycidyl ether, polyethylene glycol diglycidyl ether, bisphenol A diglycidyl ether, bisphenol F diglycidyl ether, diglycidyl phthalate, dimer acid diglycidyl ester, triglycidyl isocyanurate, diglycerol triglycidyl ether, sorbitol tetraglycidyl ether, N,N,N,N-tetraglycidyl-m-xylenediamine, 1,3-bis(N,N-diglycidylaminomethyl)cyclohexane, and N,N,N,N-tetraglycidyldiaminodiphenylmethane.

Examples of the acid anhydride compound include aliphatic dicarboxylic acid anhydrides and aromatic polycarboxylic acid anhydrides.

Examples of the aliphatic dicarboxylic acid anhydrides include maleic anhydride, hexahydrophthalic anhydride, hexahydro-4-methyl phthalic anhydride, bicyclo[2.2.1]heptan-2,3-dicarboxylic anhydride, 2-methylbicyclo[2.2.1]heptan-2,3-dicarboxylic anhydride, and tetrahydrophthalic anhydride.

Examples of the aromatic polycarboxylic acid anhydrides include phthalic anhydride and trimellitic anhydride.

Examples of the isocyanate compound include xylylene diisocyanate, hexamethylene diisocyanate, and tolylene diisocyanate, as well as multimers, derivatives, and polymers thereof. These compounds may be used singly, or in combination of two or more kinds thereof.

The crosslinking agent may be a product. Examples of a crosslinking agent product include “RIKACID MH-700G” manufactured by New Japan Chemical Co., Ltd.

The above-described adhesive layer contains a reaction product of the copolymer and the crosslinking agent, and the content of the crosslinking agent is preferably from 0.002 parts by mass to 3.000 parts by mass with respect to a total of 100 parts by mass of the monomers configuring the copolymer.

The content of the crosslinking agent is preferably from 0.002 parts by mass to 3.000 parts by mass with respect to a total of 100 parts by mass of the monomers configuring the copolymer and, from the standpoint of, for example, obtaining an adhesive layer in which an adhesive residue is hardly generated and a stress on the flatness of an original plate is mitigated, the content of the crosslinking agent is more preferably from 0.002 parts by mass to 2.00 parts by mass, still more preferably from 0.005 parts by mass to 2.000 parts by mass, yet still more preferably from 0.010 parts by mass to 1.000 parts by mass, particularly preferably from 0.100 parts by mass to 0.500 parts by mass.

When an upper limit of the content of the crosslinking agent is 3.000 parts by mass or less, the crosslinking density of the alkyl (meth)acrylate copolymer is prevented from being excessively high. Therefore, it is believed that the adhesive absorbs the stress applied to a photomask, mitigating the effect of the adhesive layer on the flatness of the photomask. A lower limit of the content of the crosslinking agent is preferably 2.000 parts by mass or less, more preferably 1.000 parts by mass or less.

Meanwhile, when the lower limit of the content of the crosslinking agent is 0.002 parts by mass or more, since the crosslinking density is prevented from being excessively low, it is believed that the ease of handling during the production process is maintained, and the generation of adhesive residue is unlikely to occur at the time of peeling the pellicle from a photomask.

As long as the content of the crosslinking agent is in a range of from 0.002 parts by mass to 3.000 parts by mass, a pellicle in which the generation of adhesive residue is inhibited can be obtained.

### (1.3.4.6) Catalyst

The coating composition may further contain a catalyst. By this, curing of the alkyl (meth)acrylate copolymer can be further accelerated.

The catalyst is, for example, an amine-based catalyst. Examples of the amine-based catalyst include an octylic acid salt of (1,8-diazabicyclo-(5.4.0)undecene-7), and triethylenediamine. The amine-based catalyst may be a product manufactured by San-Apro Ltd., such as “DBU”, “DBN”, “U-CAT”, “U-CAT SAT”, or “U-CAT SA102”.

The content of the catalyst is preferably from 0.01 parts by mass to 3.00 parts by mass, more preferably from 0.10 parts by mass to 1.00 parts by mass, with respect to 100 parts by mass of the alkyl (meth)acrylate copolymer.

### (1.3.4.7) Surface Modifier

The coating composition preferably contains no surface modifier. By this, the amount of generated outgas can be reduced.

### (1.3.4.8) Additives

If necessary, the coating composition may contain additives, such as a filler, a pigment, a diluent, an age inhibitor, and a tackifier. These additives may be used singly, or in combination of two or more kinds thereof.

### (1.3.4.9) Dilution Solvent

The coating composition may also contain a dilution solvent. By this, the viscosity of the coating composition can be adjusted. This consequently makes it easy to control the thickness and the width of the coating composition at the time of applying the coating composition to the other end surface of the pellicle frame.

Examples of the dilution solvent include propyl acetate, acetone, ethyl acetate, and toluene.

The viscosity of the coating composition is preferably 50 Pa·s or less, more preferably from 10 Pa·s to 40 Pa·s, still more preferably from 20 Pa·s to 30 Pa·s.

The viscosity of the coating composition is the viscosity determined when the temperature of the coating composition is 25° C., and can be measured using an E-type viscometer.

(1.3.5) Properties, Etc. Of Adhesive Layer

From the standpoint of, for example, inhibiting the deterioration of the adhesive layer and reducing the amount of outgas, the adhesive layer is preferably insoluble in water. The deterioration of the adhesive layer includes deterioration of the adhesive strength, mask distortion, and the like that are caused by exposure to the moisture and the like in the atmosphere. When the moisture in the air atmosphere adsorbs to the adhesive layer, the generation of outgas caused by the moisture adsorbed to the adhesive layer is likely to occur in a vacuum environment of EUV exposure or the like. The water-insolubility of the adhesive layer indicates that the moisture in the air atmosphere hardly adsorbs to the adhesive layer. Therefore, the adhesive layer that is insoluble in water can reduce the amount of outgas. From the same standpoint, it is preferred that the raw materials of the adhesive layer include the copolymer, and that the copolymer is insoluble in water.

Whether or not the adhesive layer is insoluble in water may be evaluated based on a first gel fraction. The first gel fraction represents a ratio (% by mass) of the mass of the adhesive layer after a first treatment with respect to the mass of the adhesive layer prior to the first treatment. The first treatment refers to a treatment in which the adhesive layer is immersed in water and then stirred with heating at 60° C. for 3 hours to obtain a residue of the adhesive layer not dissolving in water, followed by drying of the thus obtained residue at 100° C. for 3 hours. In the first treatment, the amount of water to be used is 100 parts by mass with respect to 1 part by mass of the adhesive layer. The mass of the adhesive layer after the first treatment represents the mass of the residue of the adhesive layer after the drying. The adhesive layer to be evaluated may be a test piece collected from the adhesive layer.

When the first gel fraction is 70% by mass or less, the adhesive layer may be judged to be soluble in water. When the first gel fraction is 80% by mass or less, the adhesive layer may be judged to be soluble in water. When the first gel fraction is 90% by mass or less, the adhesive layer may be judged to be soluble in water.

Whether or not the copolymer is insoluble in water may be evaluated based on a second gel fraction. The second gel fraction represents a ratio (% by mass) of the mass of the copolymer after a second treatment with respect to the mass of the copolymer prior to the second treatment. The second treatment refers to a treatment in which the copolymer is immersed in water and then stirred with heating at 60° C. for 3 hours to obtain a residue of the copolymer not dissolving in water, followed by drying of the thus obtained residue at 100° C. for 3 hours. In the second treatment, the amount of water to be used is 100 parts by mass with respect to 1 part by mass of the copolymer. The mass of the copolymer after the second treatment represents the mass of the residue of the copolymer after the drying. The copolymer to be evaluated may be a test piece collected from the copolymer.

When the second gel fraction is 70% by mass or less, the copolymer may be judged to be soluble in water. When the second gel fraction is 80% by mass or less, the copolymer may be judged to be soluble in water. When the second gel fraction is 90% by mass or less, the copolymer may be judged to be soluble in water.

From the standpoint of, for example, inhibiting the deterioration of the adhesive layer and reducing the amount of outgas, the adhesive layer may contain a metal ion and an ammonium ion. Examples of the metal ion include a sodium ion, a potassium ion, and a calcium ion.

A total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the adhesive layer.

The total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the monomers configuring the copolymer.

In order to inhibit the contamination of an apparatus with a component derived from an ion such as the metal ion, the total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the adhesive layer.

In order to inhibit the contamination of an apparatus with a component derived from an ion such as the metal ion, the total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the monomers configuring the copolymer.

### (1.3.6) Thickness

The thickness of the adhesive layer is not particularly limited, and it is preferably from 0.01 mm to 1 mm, more preferably from 0.1 mm to 0.8 mm. When the thickness of the adhesive layer is in this range, distortion of a photomask after pasting can be reduced while ensuring the adhesiveness to the photomask, so that errors in exposure can be eliminated.

### (1.4) Pellicle Frame

In one embodiment, the pellicle includes a pellicle frame.

The pellicle frame supports a pellicle film.

The pellicle frame is a cylindrical body. The pellicle frame has a through-hole. This through-hole refers to a space which an exposure light transmitting through the pellicle film passes through to reach a photomask.

The pellicle frame may also have a vent hole. When the pellicle frame is pasted to the photomask, the vent hole connects an inner space of the pellicle and an outer space of the pellicle in communication with each other. The “inner space of the pellicle” refers to a space surrounded by the pellicle and the photomask. The “outer space of the pellicle” refers to a space that is not surrounded by the pellicle and the photomask.

When viewed from the thickness direction, the rectangular pellicle frame consists of four sides.

The length of a longitudinal side is preferably 200 mm or less. The size and the like of the pellicle frame are standardized based on the type of an exposure device. The pellicle frame having a length of 200 mm or less on a longitudinal side satisfies a size standardized for exposure with EUV light.

The length of a transverse side may be, for example, from 5 mm to 180 mm, and it is preferably from 80 mm to 170 mm, more preferably from 100 mm to 160 mm.

The height of the pellicle frame (i.e., the length of the pellicle frame in the thickness direction) is not particularly limited, and it is preferably 3.0 mm or less, more preferably 2.4 mm or less, still more preferably 2.375 mm or less. By this, the pellicle frame satisfies a size standardized for EUV exposure. The height of the pellicle frame standardized for EUV exposure is, for example, 2.375 mm.

The mass of the pellicle frame is not particularly limited, and it is preferably 20 g or less, more preferably 15 g or less. This makes the pellicle frame suitable for the use in EUV exposure.

Examples of a material of the pellicle frame include aluminum, titanium, stainless steel, ceramic materials (e.g., silicon and glass), and resins such as polyethylene.

The shape of the pellicle frame corresponds to the shape of a photomask. Examples of the shape of the pellicle frame include a rectangular frame shape and a square frame shape.

### (1.5) Pellicle Film

In one embodiment, the pellicle includes a pellicle film.

The pellicle film not only inhibits the adhesion of foreign matters to the surface of a photomask but also allows an exposure light to pass therethrough during exposure. The foreign matters include dust. Examples of the exposure light include deep ultraviolet (DUV) light and EUV. EUV refers to a light having a wavelength of from 5 nm to 30 nm.

The pellicle film covers the entirety of an opening of the through-hole of the pellicle frame on one end-surface side. The pellicle film may be supported at one end surface of the pellicle frame either directly or via an adhesive agent layer (hereinafter, also referred to as “film adhesive agent layer”). This film adhesive agent layer may be a cured product of any known adhesive agent.

The pellicle film preferably has a thickness of from 1 nm to 200 nm.

A material of the pellicle film is not particularly limited, and examples thereof include carbon-based materials, SiN, and polysilicon. Examples of the carbon-based materials include carbon nanotubes (hereinafter, also referred to as “CNTs”). Thereamong, the material of the pellicle film 12 preferably contains CNTs. The CNTs may be single-wall CNTs or multi-wall CNTs.

The pellicle film may have a nonwoven fabric structure. The nonwoven fabric structure is formed by, for example, fiber-shaped CNTs.

### (1.6) Protective Film

In one embodiment, the pellicle may include a protective film (liner) if necessary.

The protective film protects at least a photomask-contacting surface of the adhesive layer. The protective film is peelable from the adhesive layer.

The protective film has a thickness of preferably from 5 μm to 500 μm, more preferably from 30 μm to 200 μm. Examples of a material of the protective film include polyester.

A mold release agent may be applied to a surface of the protective film on the side coming into contact with the adhesive layer. Examples of the mold release agent include silicone-based mold release agents and fluorine-containing mold release agents.

### (1.7) Exposure Original Plate

The pellicle according to one embodiment may be provided at an exposure original plate.

The exposure original plate includes a photomask and the pellicle according to one embodiment. The photomask has a pattern. The pellicle according to one embodiment is pasted to a surface of the photomask on the side having the pattern.

The exposure original plate includes the pellicle according to one embodiment; therefore, even when it is exposed to a high-temperature environment (e.g., from 50° C. to 60° C.), the pellicle is unlikely to be peeled off from the photomask.

In the photomask, for example, a support substrate, a reflective layer, and an absorbent layer may be disposed in layers in the order mentioned. The absorbent layer absorbs a portion of light (e.g., EUV), as a result of which a desired image is formed on a sensitive substrate (e.g., a semiconductor substrate equipped with a photoresist film). The reflective layer may be, for example, a multilayer film of molybdenum (Mo) and silicon (Si). A material of the absorbent layer may be a material having a high absorbance for EUV or the like. Examples of the material having a high absorbance for EUV or the like include chromium (Cr) and tantalum nitride.

### (1.8) Exposure Device

The pellicle according to one embodiment may be provided in an exposure device.

The exposure device includes: a light source; the exposure original plate according to one embodiment; and an optical system. The light source emits an exposure light. The optical system guides the exposure light emitted from the light source to the exposure original plate. The exposure original plate is arranged such that the exposure light emitted from the light source transmits through the pellicle film and is irradiated to the photomask.

The exposure device according to one embodiment not only is capable of forming a pattern refined by EUV or the like (e.g., a pattern having a line width of 32 nm or less), but also can perform pattern exposure in which defects in resolution caused by foreign matters are reduced even in the case of using EUV where defects in resolution caused by foreign matters tend to be a problem.

The exposure light is preferably EUV. EUV has a short wavelength and is thus readily absorbed by a gas such as oxygen or nitrogen. Therefore, exposure with EUV light is performed in a vacuum environment.

### (1.9) Method of Producing Pellicle

The method of producing a pellicle according to one embodiment is a method of producing the pellicle according to one embodiment, and includes the below-described pellicle film attaching step and the below-described adhesive layer forming step. By this method, a pellicle that includes an adhesive layer having a swelling degree of 200% or lower is obtained.

The order of performing the pellicle film attaching step and the adhesive layer forming step is not particularly limited.

### (1.9.1) Pellicle Film Attaching Step

In the pellicle film attaching step, the pellicle film is attached to one end surface of the pellicle frame.

A method of attaching the pellicle film to one end surface of the pellicle frame is not particularly limited, and one example thereof is a method of applying a known adhesive agent to one end surface of the pellicle frame to form a film adhesive agent layer and subsequently arranging the pellicle film on this film adhesive agent layer.

### (1.9.2) Adhesive Layer Forming Step

In the adhesive layer forming step, the above-described coating composition is applied to the other end surface of the pellicle frame and then heated to form an adhesive layer. As a result, the coating composition is dried and cured, whereby an adhesive composition (adhesive layer) is obtained.

### (1.9.2.1) Application Method

A method of applying the coating composition to the other end surface of the pellicle frame is not particularly limited and, for example, a method using a dispenser may be employed.

The thickness of the coating composition is preferably from 0.1 mm to 4.5 mm, more preferably from 0.1 mm to 3.5 mm, still more preferably from 0.2 mm to 2 mm.

### (1.9.2.2) Heat-Drying

A method of heating the coating composition is not particularly limited, and any known method may be employed.

The temperature of heating the coating composition is selected as appropriate in accordance with, for example, the boiling points of a solvent and a residual monomer, and the decomposition temperature and the like of the alkyl (meth)acrylate copolymer, and it is preferably from 50° C. to 200° C., more preferably from 60° C. to 190° C.

By heating the coating composition, volatile compounds such as a solvent and a residual monomer are removed from the resulting adhesive layer.

When the coating composition contains a crosslinking agent, the functional group of the alkyl (meth)acrylate copolymer and the crosslinking agent are reacted with each other by the heating to form a crosslinked structure in the adhesive layer, yielding a reaction product of the alkyl (meth)acrylate copolymer and the crosslinking agent. By this heat-drying, the adhesive layer tightly adheres to the pellicle frame surface, as a result of which the pellicle frame and the adhesive layer are integrated.

### (2) Modification Example

The pellicle according to a modification example of the disclosure includes: a pellicle frame; a pellicle film supported at one end surface of the pellicle frame; and an adhesive layer provided at another end surface of the pellicle frame.

The adhesive layer contains a copolymer of an alkyl (meth)acrylate monomer and a monomer (functional group-containing monomer) having a functional group that is reactive with at least one of an isocyanate group, an epoxy group, or an acid anhydride, and

the alkyl (meth)acrylate monomer may contain at least one of an alkyl group having from 1 to 3 carbon atoms or an alicyclic alkyl group.

In this modification example, the pellicle has the above-described constitution, and is thus less likely to generate outgas.

The pellicle according to the modification example is the same as the pellicle according to one embodiment, except that the adhesive layer contains the above-described copolymer and the alkyl (meth)acrylate monomer contains at least one of an alkyl group having from 1 to 3 carbon atoms or an alicyclic alkyl group, and that the adhesive layer does not have to have a swelling degree, which is represented by the above Equation (A), of 200% or lower. For the description of the modification example of the disclosure, the above description of one embodiment of the disclosure can be incorporated.

The alkyl (meth)acrylate monomer, the content of the alkyl (meth)acrylate monomer, the functional group-containing monomer, and the content of the functional group-containing monomer are the same as in one embodiment.

In the modification example, the swelling degree is preferably 200% or lower.

The swelling degree is the same as in one embodiment.

In the modification example, the pellicle preferably has an amount of generated outgas, which is determined by converting the amount of gas generated by performing the above-described (a) to (d) in the order mentioned into the amount of n-decane, of 0.2 μg or less. The amount of generated outgas is the same as in one embodiment.

In the modification example, the pellicle includes an adhesive layer. The adhesive layer is the same as in one embodiment.

The adhesive layer preferably has a glass transition temperature Tg of from −25° C. to 10° C. The glass transition temperature Tg of the adhesive layer is the same as in one embodiment.

The coating composition is the same as in one embodiment.

In the modification example, the adhesive composition contains an acrylic adhesive.

The acrylic adhesive is the same as in one embodiment.

The content of the alkyl (meth)acrylate monomer is preferably from 80 parts by mass to 99.5 parts by mass with respect to a total of 100 parts by mass of the monomers configuring the copolymer.

The content of the functional group-containing monomer is preferably, for example, from 1 part by mass to 20 parts by mass with respect to a total of 100 parts by mass of the monomers configuring the copolymer.

The adhesive layer preferably contains a reaction product of the copolymer and a crosslinking agent, and the content of the crosslinking agent is preferably from 0.002 parts by mass to 3.000 parts by mass with respect to a total of 100 parts by mass of the monomers configuring the copolymer.

The thickness of the adhesive layer is the same as in one embodiment.

In the modification example, the pellicle includes a pellicle frame. The pellicle frame is the same as in one embodiment.

In the modification example, the pellicle may include a protective film (liner) if necessary. The protective film is the same as in one embodiment.

In the modification example, the pellicle may be provided at an exposure original plate.

The exposure original plate includes a photomask and the pellicle according to the modification example. The photomask has a pattern. The pellicle according to the modification example is pasted to a surface of the photomask on the side having the pattern.

The exposure original plate includes the pellicle according to the modification example; therefore, even when it is exposed to a high-temperature environment (e.g., from 50° C. to 60° C.), the pellicle is unlikely to be peeled off from the photomask.

The photomask is the same as in one embodiment.

In the modification example, the pellicle may be provided in an exposure device. The exposure device includes: a light source; the exposure original plate according to the modification example; and an optical system. The light source emits an exposure light. The optical system guides the exposure light emitted from the light source to the exposure original plate. The exposure original plate is arranged such that the exposure light emitted from the light source transmits through the pellicle film and is irradiated to the photomask.

The exposure device according to the modification example not only is capable of forming a pattern refined by EUV or the like (e.g., a pattern having a line width of 32 nm or less), but also can perform pattern exposure in which defects in resolution caused by foreign matters are reduced even in the case of using EUV where defects in resolution caused by foreign matters tend to be a problem.

In the modification example, the exposure light is preferably EUV. EUV has a short wavelength and is thus readily absorbed by a gas such as oxygen or nitrogen. Therefore, exposure with EUV light is performed in a vacuum environment.

The method of producing a pellicle according to the modification example is the same as the method of producing a pellicle according to one embodiment.

### EXAMPLES

The disclosure will now be described in more detail by way of Examples; however, the inventions of the disclosure are not limited only to the below-described Examples.

The components used in Examples and Comparative Examples are as follows.

### <Alkyl (Meth)Acrylate Monomers>

EA: ethyl acrylate (number of carbon atoms of alkyl group: 2)
MMA: methyl methacrylate (number of carbon atoms of alkyl group: 1)
BA: butyl acrylate (number of carbon atoms of alkyl group: 4)
CHA: cyclohexyl acrylate (alicyclic alkyl group)

### <Functional Group-Containing Monomers>

4-HBA: 4-hydroxybutyl acrylate
HEMA: 2-hydroxyethyl methacrylate
GMA: glycidyl methacrylate
IEMA-type modified HEMA: 2-isocyanatoethyl methacrylate-type modified 2-hydroxyethyl methacrylate

### <Crosslinking Agents>

“RIKACID MH-700G” (alicyclic acid anhydride), manufactured by New Japan Chemical Co., Ltd.
AIBN: 2,2′-azobisisobutyronitrile (10-hour half-life temperature: 65° C.)

### <Polymerization Solvent>

propyl acetate

### <Catalyst>

Amine-based catalyst: “U-CAT SA-102” (chemical formula: (1,8-diazabicyclo-(5.4.0)undecene-7) octylate), manufactured by San-Apro Ltd.

### Example 1

An alkyl (meth)acrylate copolymer was prepared by a well-known method.

Specifically, a reaction vessel equipped with a stirrer, a thermometer, a reflux condenser, a dripping device, and a nitrogen introduction tube was prepared. To this reaction vessel, a polymerization solvent (180 parts by mass) was added, and a mixture (423.4 parts by mass) of EA/4-HBA/HEMA/GMA/crosslinking agent was further added at a mass ratio of 378/12.6/21/8.4/3.4. In a nitrogen atmosphere, this reaction solution was allowed to react at 85° C. for 6 hours and then at 95° C. for 2 hours, whereby an acrylic copolymer solution having a nonvolatile component (copolymer) concentration of 70% by mass (weight-average molecular weight: 119,000) was obtained.

To the thus obtained acrylic copolymer solution (143 parts by mass), the crosslinking agent (0.28 parts by mass) and the catalyst (0.93 parts by mass) were added, and the resultant was mixed with stirring to obtain a coating composition.

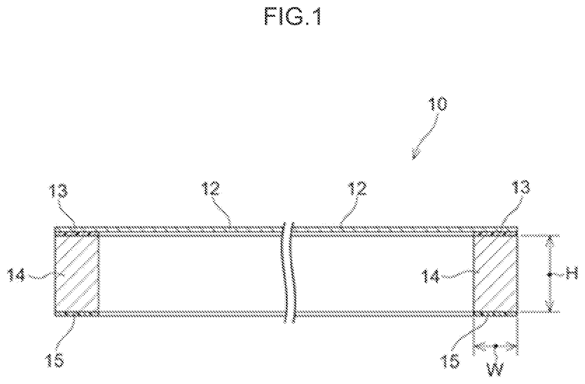

As illustrated in FIG. 1, an anodized aluminum pellicle frame (external dimensions: 149 mm×115 mm, frame height H: 4.5 mm, frame width W: 2 mm) was prepared as a pellicle frame 14. The above-prepared coating composition was applied to one end surface of the pellicle frame 14 using a dispenser. This was dried at 100° C. for 120 minutes, and a protective film was arranged on the thus dried coating composition, and then dried at 120° C. for 20 hours to form an adhesive layer 15 (thickness: 0.2 mm) made of an adhesive composition. On the other end surface of the pellicle frame 14 (on the end surface of the side without the formation of the adhesive layer 15), a pellicle film 12 was pasted via a film adhesive agent layer 13. In this manner, a pellicle 10 was obtained.

The thus obtained pellicle 10 was evaluated by the below-described methods.

### [Measurement of Swelling Degree]

As a heating apparatus, an oven (“DES830”, manufactured by Yamato Scientific Co., Ltd.) was prepared. The pellicle 10 was arranged in the chamber of this heating apparatus. The whole pellicle 10 was heated at 120° C. for 20 hours. By this, mainly a gas originating from an unreacted raw material of the adhesive layer was released from the pellicle. Subsequently, the pellicle 10 was removed from the chamber of the heating apparatus, left to stand in 25° C. air atmosphere, and thereby cooled to room temperature. Then, a portion of the adhesive layer 15 was cut to obtain a 10-mg test piece.

A decane solution (manufactured by FUJIFILM Wako Pure Chemical Corporation, “Wako Special Grade”, standard content: capillary column GC concentration=99% or higher) was prepared. The test piece was immersed in 10 ml of this decane solution at normal temperature for 6 hours. Subsequently, the test piece was removed from the decane solution using a forceps, placed on a petri dish, and dried for 3 minutes. Thereafter, the mass of the test piece was measured using “BM-252” (manufactured by AND Inc.). The swelling degree was calculated by substituting the thus measured mass of the test piece into Equation (A).

The calculation result is shown in Table 1.

### [Measurement of Amount of Generated Outgas]

Anew pellicle 10 that had not been processed or the like was prepared separately from the pellicle 10 used for the measurement of the swelling degree.

As a heating apparatus, an oven (“DES830”, manufactured by Yamato Scientific Co., Ltd.) was prepared. The pellicle 10 was arranged in the chamber of this heating apparatus. The whole pellicle 10 was heated at 120° C. for 20 hours. By this, mainly a gas originating from an unreacted raw material of the adhesive layer was released from the pellicle.

A resin bag having a three-layer structure was prepared. This resin bag was formed of a substrate layer (material: polyethylene terephthalate (PET), thickness: 12 μm) on the outer side of the bag, an adhesive layer (material: urethane resin, thickness: 3 μm) in the middle of the bag, and a sealant layer (material: polyethylene, thickness: 40 μm) on the inner side of the bag, which layers were disposed in the order mentioned.

Subsequently, the pellicle 10 was removed from the chamber of the heating apparatus, hermetically sealed in the resin bag, and stored for 2 weeks in 25° C. air atmosphere.

After the storage, the pellicle 10 was removed from the bag, and arranged in the chamber of the heating apparatus along with an adsorbent (product name: “TENAX TA”, manufactured by GL Sciences Inc. mesh: 80/60, form: powder). The whole pellicle 10 was heated at 50° C. for 4 hours. By this, outgas generated from the pellicle 10 was adsorbed to the adsorbent.

Then, the adsorbent was removed from the chamber of the heating apparatus, left to stand in 25° C. air atmosphere, and thereby cooled to room temperature. Thereafter, the outgas adsorbed to the adsorbent was heat-extracted for 10 minutes, and the amount thereof was measured by gas chromatography (GC/MS) using the below-described analysis equipment under the below-described analysis conditions. The thus measured volume of the amount of adsorbed outgas was converted into n-decane, and the resulting converted value was defined as the amount of generated outgas of the pellicle 10. This n-decane-converted value was determined by regarding the intensity of generated gas detected by GC Mass as the detected intensity of n-decane and applying a calibration curve of n-decane prepared in advance.

The thus determined amount of generated outgas of the pellicle 10 is shown in Table 1. An acceptable range of the amount of generated outgas is 1.2 μg or less.

### <Analytical Equipment>

Gas chromatography: “QP2010 plus” (manufactured by Shimadzu Corporation)

### <Analysis Conditions>

Column: “DB-1” (inner diameter: 0.32 mm, length: 60.0 m, thickness: 1.00 μm)

Scanning range: from 35 m/z to 450 m/z

Ionization: 0.78 kV

Carrier gas: He

### [Measurement of Glass Transition Temperature (Tg)]

The glass transition temperature (Tg) of the adhesive composition (adhesive layer) prior to the pasting of the pellicle 10 onto the quartz glass substrate was measured in accordance with JIS K7112. Specifically, the glass transition temperature (Tg) of the adhesive composition prior to the pasting of the pellicle 10 onto the quartz glass substrate was measured using a differential scanning calorimeter (DSC) at a heating rate of 20° C./min in a nitrogen atmosphere.

The measurement result is shown in Table 1.

### [Measurement of Weight-Average Molecular Weight (Mw) and Number-Average Molecular Weight (Mn) of Alkyl (Meth)Acrylate Copolymer]

The GPC conditions used for measuring the weight-average molecular weight (Mw) and the number-average molecular weight (Mn) of the alkyl (meth)acrylate copolymer are as follows.

### <GPC Conditions>

Pump: “LC-10AD”, manufactured by Shimadzu Corporation

Oven: “CT020A”, manufactured by Shimadzu Corporation

Detector: “RI-101”, manufactured by Showa Denko K.K.

Data processing software: “EMPOWER 3”, manufactured by Waters Corporation

GPC columns: “PLgel MIXED-B” (7.5×300 mm)×2, manufactured by Agilent Technologies, Inc.

Column temperature: 40° C.

Elution solvent: tetrahydrofuran

Flow rate: 1.0 m/min

Sample concentration: 0.1% (w/v)

Sample injection amount: 100 μL

Standard substance: monodisperse polystyrene

### Example 2

An acrylic copolymer solution having a nonvolatile component concentration of 70% by mass (weight-average molecular weight: 138,000) was obtained by performing a reaction under the same conditions as in Example 1, except that EA, 4-HBA, and GMA were added at the respective mass ratios shown in Table 1. The thus obtained solution was applied and processed, and various evaluations of the thus obtained pellicle 10 were performed in the same manner as in Example 1.

### Example 3

An acrylic copolymer solution having a nonvolatile component concentration of 70% by mass (weight-average molecular weight: 105,000) was obtained by performing a reaction under the same conditions as in Example 1, except that EA, MMA, 4-HBA, HEMA, and GMA were added at the respective mass ratios shown in Table 1. The thus obtained solution was applied and processed, and various evaluations of the thus obtained pellicle 10 were performed in the same manner as in Example 1.

### Example 4

An acrylic copolymer solution having a nonvolatile component concentration of 70% by mass (weight-average molecular weight: 134,000) was obtained by performing a reaction under the same conditions as in Example 1, except that BA, CHA, 4-HBA, HEMA, and GMA were added at the respective mass ratios shown in Table 1. The thus obtained solution was applied and processed, and various evaluations of the thus obtained pellicle 10 were performed in the same manner as in Example 1.

### Example 5

An acrylic copolymer solution having a nonvolatile component concentration of 70% by mass (weight-average molecular weight: 134,000) was obtained by performing a reaction under the same conditions as in Example 1, except that EA, BA, 4-HBA, and GMA were added at the respective mass ratios shown in Table 1. The thus obtained solution was applied and processed, and various evaluations of the thus obtained pellicle 10 were performed in the same manner as in Example 1.

### Comparative Example 1

BA and HEMA were reacted with each other at a BA/HEMA mass ratio of 90/8.9, and the resulting reaction product of BA and HEMA was reacted with 2-isocyanatoethyl methacrylate such that a HEMA/2-isocyanatoethyl methacrylate mass ratio of 8.9/1.1 was obtained, whereby an acrylic copolymer solution, which contained BA, HEMA, and IEMA-type modified HEMA at the respective mass ratios shown in Table 1 and had a nonvolatile component concentration of 70% by mass, was prepared. The thus prepared solution was applied and processed, and various evaluations of the thus obtained pellicle 10 were performed in the same manner as in Example 1.

TABLE 1

| | Adhesive | Copolymer | | | | | |
|---|---|---|---|---|---|---|---|
| | layer | Raw material monomer | | | | Functional group-containing monomer | |
| | Swelling | EA | MMA | BA | CHA | 4-HBA | HEMA |
| | degree | (parts by | (parts by | (parts by | (parts by | (parts by | (parts by |
| | (%) | mass) | mass) | mass) | mass) | mass) | mass) |
| Comparative | 227 | 0 | 0 | 90 | 0 | 0 | 8 |
| Example 1 | | | | | | | |
| Example 1 | 148 | 90 | 0 | 0 | 0 | 3 | 5 |
| Example 2 | 132 | 90 | 0 | 0 | 0 | 8 | 0 |
| Example 3 | 124 | 77 | 13 | 0 | 0 | 3 | 5 |
| Example 4 | 120 | 0 | 0 | 47 | 43 | 3 | 5 |
| Example 5 | 173 | 77 | 0 | 13 | 0 | 8 | 0 |

| | Copolymer | | | | | | |
|---|---|---|---|---|---|---|---|
| | Functional group-containing monomer | | | | | | |
| | | IEMA-type | | | | | Evaluation |
| | | modified | | | | Adhesive | Amount of |
| | GMA | HEMA | | | | composition | generated |
| | (parts by | (parts by | Molecular weight | | | Tg | outgas |
| | mass) | mass) | Mw | Mn | Mw/Mn | (° C.) | (μg) |
| Comparative | 0 | 2 | — | — | — | −48 | 2.50 |
| Example 1 | | | | | | | |
| Example 1 | 2 | 0 | 119,000 | 30,600 | 3.9 | −16 | 0.18 |
| Example 2 | 2 | 0 | 138,000 | 29,900 | 4.6 | −20 | 0.12 |
| Example 3 | 2 | 0 | 105,000 | 31,100 | 3.4 | −7 | 0.06 |
| Example 4 | 2 | 0 | 134,000 | 41,400 | 3.2 | −17.1 | 0.30 |
| Example 5 | 2 | 0 | 136,000 | 26,100 | 5.2 | −24.2 | 0.60 |

In Table 1, “Raw material monomer” indicates each alkyl(meth)acrylate monomer, and “Copolymer solution” indicates each acrylic copolymer solution.

The pellicle of Comparative Example 1 included a pellicle frame, a pellicle film, and an adhesive layer. In the pellicle of Comparative Example 1, the adhesive layer had a swelling degree of 227%, which is not 200% or lower. Accordingly, the amount of generated outgas was 2.50 μg, which is not 1.2 μg or less. As a result, the pellicle of Comparative Example 1 was found not to be a pellicle that is less likely to generate outgas.

The pellicles of Examples 1 to 4 each included the pellicle frame 14, the pellicle film 12, and the adhesive layer 15. In the pellicles of Examples 1 to 4, the adhesive layer had a swelling degree of from 120% to 148%, which is 200% or lower. Accordingly, the amount of generated outgas was 0.30 μg, which is 15% or less of that of Comparative Example 1 even in Example 4 where the largest amount of outgas was generated. As a result, the pellicles of Examples 1 to 4 were found to be pellicles that are less likely to generate outgas.

The disclosure of Japanese Patent Application No. 2021-148632 filed on Sep. 13, 2021 is hereby incorporated by reference in its entirety.

All the documents, patent applications, and technical standards that are described in the present specification are hereby incorporated by reference to the same extent as if each individual document, patent application, or technical standard is concretely and individually described to be incorporated by reference.

1. A pellicle, comprising:
a pellicle frame;
a pellicle film supported at one end surface of the pellicle frame; and
an adhesive layer provided at another end surface of the pellicle frame,
wherein the adhesive layer has a swelling degree, which is represented by the following Equation (A), of 200% or lower:
[post-immersion mass of 10-mg test piece collected from the adhesive layer/10 mg]×100 Equation (A):
wherein, in Equation (A), the post-immersion mass represents a mass of the test piece after a 6-hour immersion of the test piece in 10 ml of a decane solution having a capillary column GC concentration of 99.0% by mass or higher.

2. The pellicle according to claim 1, wherein the adhesive layer has a glass transition temperature Tg of from −25° C. to 10° C.

3. The pellicle according to claim 1, wherein the adhesive layer comprises a copolymer of an alkyl (meth)acrylate monomer and a monomer comprising a functional group that is reactive with at least one of an isocyanate group, an epoxy group, or an acid anhydride.

4. The pellicle according to claim 3, wherein the alkyl (meth)acrylate monomer comprises at least one of an alkyl group having from 1 to 3 carbon atoms or an alicyclic alkyl group.

5. The pellicle according to claim 3, wherein the content of the alkyl (meth)acrylate monomer is from 80 parts by mass to 99.5 parts by mass with respect to a total of 100 parts by mass of the monomers configuring the copolymer.

6. The pellicle according to claim 3, wherein the content of the monomer comprising the functional group is from 0.5 parts by mass to 20 parts by mass with respect to a total of 100 parts by mass of the monomers configuring the copolymer.

7. The pellicle according to claim 3, wherein:
the adhesive layer comprises a reaction product of the copolymer and a crosslinking agent, and
the content of the crosslinking agent is from 0.002 parts by mass to 3.000 parts by mass with respect to a total of 100 parts by mass of the monomers configuring the copolymer.

8. The pellicle according to claim 1, wherein an amount of generated outgas, which is determined by converting an amount of gas generated by performing the following (a) to (d) in the following order into an amount of n-decane, is 1.5 μg or less:
(a) heating the pellicle at 120° C. for 20 hours;
(b) storing the pellicle in a hermetically sealed resin bag for 2 weeks in a 25° C. air atmosphere;
(c) allowing an adsorbent to absorb a gas released by heating the pellicle at 50° C. for 4 hours; and
(d) heating the adsorbent for 10 minutes to measure the amount of the gas adsorbed in (c).
